(19) United States
(12) Patent Application Publication
(10) Pub. No.: US 2005/0005212 A1
(43) Pub. Date: Jan. 6, 2005

(54) Electronic component with output buffer control

(76) Inventors: Majid Ghameshlu, A-Wien (AT); Karlheinz Krause, Planegg (DE); Herbert Taucher, Modling (AT)

Correspondence Address: Siemens Corporation;Intellectual Property Department, 170 Wood Avenue South, Iselin, NJ, 08830, US

(21) Appl. No.: 10/494,550

(22) PCT Filed: Oct. 28, 2002
(86) PCT No.: PCT/EP02/12029

(30) Foreign Application Priority Data
Nov. 2, 2001 (EP) 01126134.4

(51) Int. Cl. G01R 31/28

(52) U.S. Cl. 714/726

(57) ABSTRACT

According to the invention, the aim of an optimisation of the timing in normal mode with no disadvantage to, or limitation of the scanning mode may be achieved for an electronic component with an integrated circuit comprising output flip-flops, the output data of which in the normal mode of the component is transmitted to an output buffer on the component, controlled by a control signal, the control signal being provided in normal mode by an output-enable flip-flop provided for the output buffer and in a scan mode for the component by scan-enable cells. Said aim is achieved, whereby a device is provided, in which in the scan mode, a scan-enable cell controls at least two output buffers.

### CROSS REFERENCE TO RELATED APPLICATIONS

This application is the US National Stage of International Application No. PCT/EP02/12029, filed Oct. 28, 2002 and claims the benefit thereof. The International Application claims the benefits of European application No. 01126134.4 filed Nov. 2, 2001, both of the applications are incorporated by reference herein in their entirety.

### FIELD OF INVENTION

The invention relates to an electronic component with an integrated circuit which features output flip-flops of which the output data is forwarded in the component's normal mode to an output buffer of the component in each case which is controlled by a control signal, where the control signal is supplied in the normal mode by an output enable flip-flop and in a scan mode of the component by the scan enable cells.

### BACKGROUND OF INVENTION

Electrical components of this type are frequently embodied as Application Specific Integrated Circuits (ASICs) which are subjected in their manufacturing to comprehensive qualification procedures. ASICs are a collection of circuits with simple functions, such as flip-flops, inverters, NANDs and NORs, as well as of more complex structures such as memory arrangements, adders, counters and phase locked loops. The various circuits are combined in an ASIC to execute a specific application. In this case ASICs are used in a large number of products such as consumer products, video games, digital cameras, in vehicles and PCs, as well as in high-end technology products such as workstations and supercomputers.

Various “Design For Test” (DFT) methods are known for testing the functionality of ASICs. The advantage of a DFT method lies in the fact that, even during the construction of the component, circuit elements are inserted which allow later scan-based testing, reduce the number of test points needed on the board of the ASIC and at the same time get around the problem of non-availability of access points on the chip.

An example of such a DFT method is what is known as the Boundary Scan (BS) method which is a method for chip and board testing standardized in accordance with IEEE 1149. Details of Boundary Scan are described for example in the book “Boundary-Scan-Test: A Practical Approach”, H. Bleeker, Kluwer Academic Publishers 1993, ISBN 0-7923-9296-5. All connection tests at board level in the production of complex Printed Circuit Boards (PCBs) are based on the Boundary Scan method. For this reason this standard is also implemented in other Integrated Circuits and ASICs. As a result of the hardware preparations which are made for Boundary Scan there are however certain restrictions which arise as regards input and output timing in normal operation of the chip, especially for timing-critical interfaces.

With a classical chip arrangement, two chips (chip A and chip B) form an interface on a board, with a single data path of the interface leading from an output flip-flop, abbreviated to output FF via the multiplexer of a boundary scan output cell, an Input/Output (I/O) buffer, the board, an input buffer of chip B to the timing input FF.

This classical arrangement results in two requirements as regards timing:

The maximum runtime from the last flip-flop in chip A to the first flip-flop in chip B must be adhered to, which means a restriction of the runtime from the flip-flop in chip A to the output pin on chip A.

The deviation of the individual data paths, i.e. the skew, of the interface may not exceed set limits. In general terms skew on a data bus means that undesired runtime difference between the slowest and the fastest signal on the data bus.

Since the deep-submicron effects for chip technologies with drawn structure widths of 0.25 μm (and below) cause the delay times of the lines on the chip to dominate the delays of the individual gates, an effort is made in the layout of the chip to place the last flip-flop of an output (and the subsequent multiplexer) as close as possible to the I/O buffer. This also applies to the output-enable flip-flop, abbreviated to output-enable FF, which in the classical arrangement controls all I/O buffers of a chip. It should be noted here that the term output buffer is used below as a synonym for I/O buffer.

The underlying object of U.S. Pat. No. 6,266,801 B1 is to make the output Q of a logical core of an ASIC predictable to achieve an accurate as possible layout of this output for the load conditions and to avoid overdimensioning. U.S. Pat. No. 6,266,801 B1 discloses an arrangement in which in normal mode a single control output Q of the core supplies the output-enable signal for a plurality of output buffers. The problem with this arrangement however is that the enable lines to the individual output buffers necessarily have to be of different lengths and feature different signal delay times.

To put it more precisely a problem arises from the I/O buffers of a wider interface being distributed over one edge of the chip and thus the paths of the output-enable FFs to the I/O buffers having different delay times. The last flip-flop in the enable paths can thus not now be placed in the optimum position for all I/O buffers, but only for one buffer of the group of I/O buffer controlled by the output-enable FF.

To enable the boundary scans to be performed, boundary scan cells are provided between the last or first flip-flop of the chips and the I/O buffers, as well as between the output-enable FFs and the I/O buffers which can be interconnected in a scan mode to form a shift register. The I/O buffers are also controlled in scan mode, but in the scan mode the delay time problems (as described above in relation to normal operation) play a subordinate role, since the operating frequency in scan mode is in the region of a tenth (typically 12.5 MHz) of the clock frequency for normal mode.

The delay time problem only arises with use and application of timing-critical interfaces, with the critical area being reached at a bus frequency of 133 MHz. However, because of ever higher bus frequencies, time-critical interfaces in Integrated Circuits, especially in ASICs, may become the rule in future.

A known way of getting around the problem of differences in delay times is to provide a separate output enable FF with subsequent boundary scan cell which control precisely one I/O buffer. Although at first glance this architecture resolves the primary problem of I/O-timing, since the individual output-enable FFs can be arranged to accord with the timing criteria, a major problem arises as regards the test run times, since the boundary scan chain becomes significantly longer through the additional boundary scan cells assigned to the output-enable FFs. As well as this the corresponding additional hardware for executing the boundary scan tests is to be implemented and the simulation times increase.

An example is given below to clearly show the dependency of the simulation delay time on the number of output-enable FFs: Assuming an SDRAM interface with a total of 52 address pins, 134 data pins, 18 ECC pins and a number of control pins, the classical arrangement described above, i.e. the arrangement in which delay time problems can occur, needs 12 output-enable FFs, of which 9 are used for data pins. The chip concerned has a total of 1291 boundary scan cells, 757 of which are boundary scan output cells.

For a simulation of a complete test of the correct wiring one of the things that must be done is to preload with “1” all output-enable FFs, except one, using a shift cycle, which requires as many clocks as make up the length of the boundary scan chain (1292 clocks), so that what is know as a “ones” test can be used to verify the actual enabling or activation of the associated pins. Thus a total of 12 shift cycles is needed for the pins of the SDRAM interface, compared to the 87 shift cycles needed to verify the complete chip.

If one now also allocates its own output-enable FF to each data output pin, in order to get around the delay time problems described above for normal operation, the number of data enables would rise from 9 to 134. A total of 212 shift cycles would now bee needed, meaning an increase in simulation time by a factor of 2.43. It should be noted that only one interface was considered here.

A further example shows the dependence of the test delay time for module fabrication on the number of output-enable FFs: The MECA ASIC with 1294 boundary scan cells, 672 boundary scan output cells and 71 Boundary scan enable cells, i.e. boundary scan cells to control the I/O buffer in scan mode is shown as an example here. Since one boundary scan enable cell is provided for each boundary scan output cell, the length of the boundary scan chain increases by 672−71=601 to 1294+601=1895 boundary scan cells. This means that the length of the boundary scan chain increases by 46% and the test time by around the same percentage figure.

It can be seen from this example that it is necessary to minimize the number of boundary scan cells and especially the number of boundary scan enable cells.

### SUMMARY OF INVENTION

The object underlying the invention is thus that of creating an electronic module in which no delay time and skew problems arise, and still keeping the hardware and design overhead for the boundary scan method as low as possible.

In accordance with the invention this object is achieved by an electronic chip for which in scan mode a scan enable cell controls at least two output buffers.

This makes it possible to minimize and balance the delay time from the last output-side flip-flop of the data and enable path, without having to insert a clock tree for these networks and without the test, simulation and test times becoming being extended.

In an advantageous embodiment of the present invention boundary scan cells are arranged between the output FFs and the corresponding output buffers which in scan mode can be interconnected into a shift register. The full boundary scan functionality is thereby achieved.

In accordance with another advantageous embodiment each output-enable FF is connected via a control multiplexer to an output buffer to provide separate control of the output buffer in scan and normal mode.

In accordance with an advantageous aspect of the present invention, in normal mode the control multiplexer delivers the control signal of the output-enable FF to the output buffer and in scan mode the control signal of a scan-enable cell to the output buffer, which offers mode-dependent control of the output buffer.

In accordance with an especially advantageous aspect of the present invention the scan-enable cells feature a first control output to control an output buffer and a second control output to control at least one further output buffer. This allows the inventive scan-enable cells to control a number of output buffers but simultaneously to possess the boundary scan functionality in accordance with the IEEE 1149 Standard.

In accordance with a further especially advantageous aspect of the present invention the scan-enable cell is a boundary scan cell assigned to an output-enable FF with two control outputs, in order to provide the present invention, starting from the boundary scan cells known from the IEEE 1149 Standard.

In accordance with another embodiment of the present invention the control multiplexer of the output-enable FF which is assigned a scan-enable cell is the output multiplexer of the boundary scan cell in order to save on an additional component, namely a control multiplexer and integrate the scan-enable cell into the shift register.

Advantageously the additional control output of the scan-enable cell is connected via buffer control lines to at least one control multiplexer of a further output buffer. This makes it possible for the scan-enable cell to control a number of output buffers in scan mode which is greater that the number of output buffers controlled in normal mode by an output-enable FF.

In accordance with an especially advantageous embodiment of the present invention the boundary scan cells are interconnected in scan mode with the scan-enable cells into a single shift register in order to provide a shift register for testing all scan cells.

With another advantageous embodiment the control multiplexer receives mode control signals over mode control lines output by a central controller. An especially simple to implement control of the control multiplexer is thus provided.

With another further embodiment all control multiplexers are switched into the same status by the mode control signals. This makes uniform control of the output buffers by the scan-enable cells in scan mode and by the output-enable FF in normal operation possible.

With another further embodiment the same mode control signals that control the control multiplexer also control the multiplexers of the boundary scan cells which determine whether data from the output FFs or inserted data from the shift register is to be output via the output buffer. In this way the control of the control multiplexers can be combined especially easily with control of the boundary scan cells.

### BRIEF DESCRIPTION OF THE DRAWING

An exemplary embodiment of the invention is shown in the drawing and is described in more detail below. The single FIGURE of the application shows a schematic diagram of an electronic component in accordance with the present invention.

### DETAILED DESCRIPTION OF INVENTION

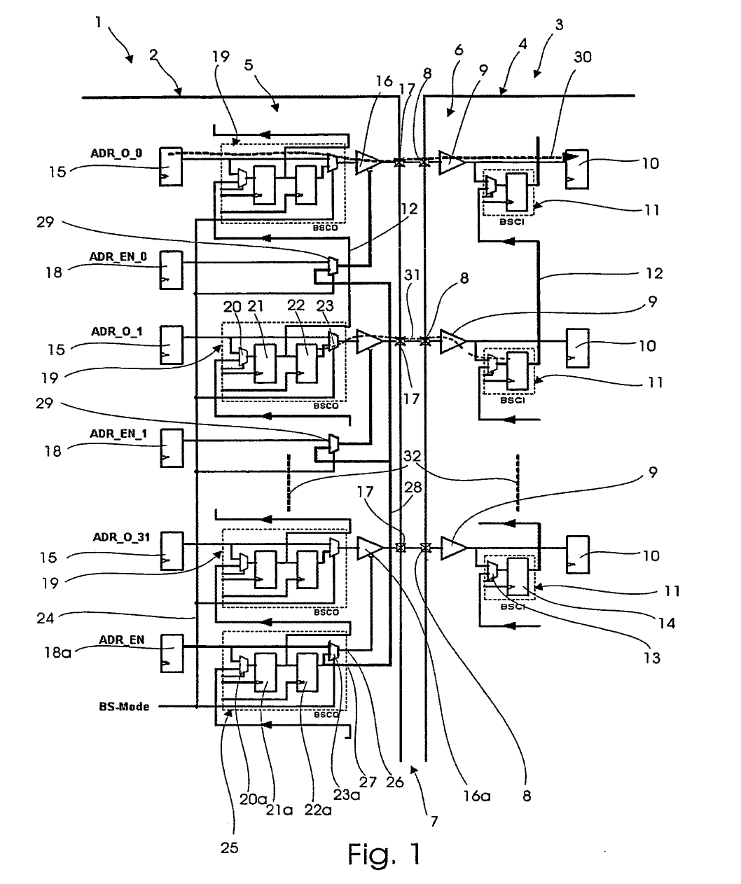

FIG. 1 shows an electronic component 1 in accordance with the invention with an integrated circuit 2 and a second electronic component 3 also with an integrated circuit 4 The electronic components involved here are Application Specific Integrated Circuits (ASICs) generally comprising an ASIC core, an input area and an output area. FIG. 1 merely shows the output area 5 of the first electronic component 1, as well as the input area 6 of the second electronic component 3.

The two electronic components 1, 3 are connected to each other on a board (not shown) via an interface 7 which is defined by the addresses ADR 0_{—}0 to ADR_O_{—}31. Interface 7 is used for exchange of data between the components or ASICs 1, 3.

The input area 6 of the second ASIC 3 comprises input pins 8 which are connected to input buffers 9, and these in their turn are connected to the input FFs 10. The clocking input —flip-flop 10 or input FFs forward the entered and clocked data to the ASIC core (not shown) in which case the input FFs 10 generally belong to the core. Parallel-connected boundary scan input cells 11 are located between the input buffers 9 and input FFs 10. The boundary scan input cells 11 (BSCI) comply with the IEEE 1149 Standard and in scan mode can be interconnected via shift register lines 12 into a shift register, to accept data applied to the input pins 8 and shift out the test data for analysis via the shift register formed. In this case input data is first accepted into BSCI flip-flop 14 of BSCIs 11. Subsequently to form the shift register BSCI multiplexer 13 is connected so that BSCIs for the shift register via shift register lines 12.

In output area 5 of ASIC 1 there are output FFs 15, which receive data output by the ASIC core from previous circuit elements not shown in the diagram. The output FFs 15 generally belong the ASIC core and connected to input/output buffers or I/O buffers 16. The I/O buffers 16 are tristate output buffers 16 in the preferred exemplary embodiment. They will just be referred to as output buffers below but it should be noted that other buffers, for example bidirectional buffers can be used within the framework of the present invention. Output buffers 16 can assume the logical states 1, 0 as well as a high-impedance state Z.

Output buffers 16 are connected to output pins 17 which enables data to be forwarded from ASIC 1 and onwards to the second ASIC 3. Output buffers 16 have an enable input which is connected via a control multiplexer 29 described later with a relevant output-enable FF 18, 18a. The output enable FFs 18, 18a control the status of output buffers 16 in normal operation of the ASIC 1 by a control signal. The output-enable FFs 18, like the output FFs 15, obtain their data from upstream circuit elements of the electronic component 1 not shown and are generally assigned to the ASIC core.

Boundary scan output cells (BSCO) 19 are located between the output FFs 15 and the output buffers 16. The BSCO 19 comply with the IEEE 1149 Standard and thus comprise a BSCO input multiplexer 20, a first BSCO flip-flop 21, a second BSCO flip-flop 22 as well as a BSCO output multiplexer 23. Depending on status, the BSCO input multiplexer 20 either enters inserted data or data from the output FF 15 in into the first BSCO flip-flop 21. This forwards the data on one side via shift register lines 12 to the BSCO input multiplexer 20 of the adjacent BSCO 19 following on in the shift register and on the other hand to the second BSCO flip-flop 22. The BSCO-flip-flop 22 output, as well as the output of the output FF 15 supply the inputs for the BSCO output multiplexer 23, so that control multiplexer 23, if this is connected in scan mode, outputs the data from the second BSCO flip-flop 22 or in normal operation the outputs of the output FF via the output buffer 16.

For a more detailed description of the functions of a BSCO the reader is referred to the IEEE 1149 Standard. However it should be pointed out here that the BSCO output multiplexer 23 obtains via mode control lines 24 a mode control signal from a tap controller not shown in the diagram. The mode control signal determines whether data from the output FFs 15 or where necessary data inserted as test vectors into BSCO 19 from the second BSCO flip-flop 22 is to be forwarded to the output buffers 16.

In accordance with the present invention an adapted BSCO 25 is connected between an output-enable FF 18a, labeled ADR EN in FIG. 1, and the associated output buffer 16a, referred to below as scan-enable cell 25. Scan-enable cell 25 is used for control of the output buffers 16 of ASIC 1 in a scan mode of ASIC 1, with, in the preferred exemplary embodiment of the scan mode a boundary scan being in accordance with the IEEE 1149 Standard but any other scan method for testing the ASICs 1 also able to be used.

The scan-enable cell 25 is identical to BSCO 19, and in this respect features a first input multiplexer 20a, a first flip-flop 21a, a second flip-flop 22a and also a second output multiplexer 23a which perform similar functions to their BSCO equivalents. Input multiplexer 20a however supplies either output buffer control data from the output-enable FF 18a or inserted data to the first flip-flop 21a.

The scan-enable cell of the present invention further features a fist control output 26 and a second control output 27. The output of output multiplexer 23a is connected to the first control output 26 and delivers a mode control signal to the enable input of output buffer 16a. In normal mode output multiplexer 23a is switched by the mode control signal so that a mode control signal of the output-enable FF 18a is present at the output buffer 16a and controls it. In scan mode the output multiplexer 23a is switched by the mode control signal so that data from the second flip-flop 22a of the scan-enable cell 25 will be applied to output buffer 16 as a control signal.

The second control output 27 connects the second flip-flop 22a of the scan-enable cell 25 via buffer control lines 28 with the remaining output buffers 16, i.e. with the output buffers which are not controlled via the first control output 26.

A control multiplexer 29 is arranged in each case between the output buffers 16 which are not controlled via the first control output 26 and the output-enable FF 18 belonging to the relevant output buffer 16. The control multiplexer 29 receives as inputs the mode control signal of the output-enable FF 18 and the mode control signal of the second flip-flop of the scan-enable cell 25. Depending on the status of the control multiplexer 29 one of the two control signals is forwarded to the relevant output buffer 16 to control it. This means that whereas in normal operation an output-enable FF 18 controls one output buffer 16 in each case, the scan-enable cell controls all output buffers in scan mode.

In the preferred exemplary embodiment the tap controller not shown in the diagram controls the status of control multiplexer 29 by sending the mode control signal via the mode control lines 24. This means that the same mode control signal is present at the control multiplexer 29 as is present at the BSCO output multiplexers 23 and at the output multiplexer 23a and are preferably all switched into the same state.

The different operating modes of the ASICs are described below:
a. In normal mode the output FFs 15 receive data for output from the first ASIC 1 and input to the second ASIC 3. The data path for normal operation is shown in FIG. 1 for the example of the IP address ADR 0_{—}0 by the arrow labeled 30. The data from the output FF 15 arrive at the output buffer 16, since the BSCO output multiplexer 23 is not activated for scan mode. In normal operation the output-enable FF 18 (ADR EN_0) sends a mode control signal to the output buffer 16, since the control multiplexer 29 in its turn is not switched into scan mode. When the mode control signal of the output-enable FF 18 has activated output buffer 16, the data output from output FF 15 arrives via output FF 17 and the Interface 7 at input 8 of the second ASIC 3. The data is now subsequently clocked in input 10 of the second ASIC 3.
b. In scan mode ASICs 1, 3 will be tested after fabrication. In the preferred exemplary embodiment scan mode is a boundary scan test, where a connection test of the outputs or inputs of components 1, 3 is undertaken. For this BSCO 19 and BSCI 11, as well as the scan-enable cells 25 of a module are interconnected to form a shift register by controlling the BSCO input multiplexer 20, the BSCI multiplexer 13 and the input multiplexer 20a of the scan-enable cell 25. In this case the BSCOs 19, BSCIs 11 and the at least one scan-enable cell 25 are connected via the shift register lines 12. With timing of typically 12.5 MHz, which corresponds to timing of roughly a tenth of normal operation, test vectors are now inserted into the shift register and arrive at the second BSCO flip-flop 23 as well as in the second flip-flop of scan-enable cell 25. A typical example of the data flow via interface 7 is shown by the arrow labeled 31 in FIG. 1. The data from the second BSCO-flip-flop 22 goes past the BSCO output multiplexer 23 to output buffer 16, since the BSCO output multiplexer 23 is switched via the mode control lines 24 into scan mode. From output buffer 16 the data travels on via interface 7 to input buffer 9 of the second electronic component 3. Here the data arrives at the BSCI control multiplexer 13 switched into scan mode and in the BSCI flip-flop 14. After the data has been received by ASIC 3 and has been stored in BSCI 19, the shift register can be established by switching over the BSCI control multiplexer 13 and read out from ASIC 3 for analysis.

In summary it can be said that in normal mode the control of an output buffer 16 is undertaken by an assigned output-enable-flip-flop 18 in each case. This gives the advantage that the flip-flop 18 with the downstream control multiplexer 29 can be optimally positioned in the immediate vicinity of the output buffer 16. Only in this way is it possible to minimize and balance the delay times of the last flip-flop of the data-enable or control path to output pin 17 on the output side without having to insert a clock tree for these networks.

In scan mode on the other hand a group of output buffers 16 of is activated by a scan-enable cell 25. The result of this is that the test, simulation and tester times are not extended compared to conventional implementations, since no additional BSCO cells have to be implemented.

By switching the scan-enable cells 25, which each assume control of a group of output buffers 16 in scan mode, especially in boundary scan mode, and by using an output enable flip-flop 18 with a downstream control multiplexer 29 for control of the output buffers 16 in normal mode, the best conditions are created for the layout of an electronic component 1 for optimizing the timing in normal mode without disadvantages or restrictions for the scan mode.

Taking account of the layout in this way becomes more significant with newer technologies in the semiconductor sector, a fact already demonstrated by the increasing use of “physical compile” tools for circuit synthesis.

Finally it should be said that FIG. 1 merely shows a section of an interface between two ASICs. The dotted lines 32 are intended to show that the group formed by output FFs 15, output-enable FFs 18, BSCOs 19, output buffers 16, scan-enable cell 25, control multiplexer 29 and connections can comprise any number of elements in accordance with the scheme disclosed in FIG. 1. The same applies to the group of BSCIs 11 in ASIC 3.

In the preferred exemplary embodiment of the present invention only one scan-enable cell 25 is provided in a group which controls all output buffers 16 of the group in normal mode. It is however entirely conceivable to have groups which so large, in which even with comparatively low clocking in scan mode the control of output buffer 16 is divided up in scan mode over a number of scan-enable cells 25 in order to make it possible to optimize the timing of the control of the output buffers.

As the expert can easily verify, a number of the groups shown in FIG. 1 can also be arranged in an interface in parallel to one another, i.e. one scan-enable 25 serves a group of output buffers 16 in each case and a number of these groups together form the output area 5 of the ASIC.

1-13. (cancelled)

14. (new) an electronic component, comprising:
an output buffer controlled by a control signal; and
an integrated circuit having output flip-flops adapted to forward output data in a normal mode of the component to an output buffer of the component controlled by the control signal, wherein
the output buffer is assigned the output-enable flip-flop to supply the control signal in a normal mode, and wherein
scan-enable cells are provided to supply the control signal to each of at least two output buffers in a scan mode of the component.

15. An electronic component in accordance with claim 14, wherein boundary scan cells are interconnected to form a shift register are arranged between the output flip-flops and their corresponding output buffers in scan mode.

16. An electronic component in accordance with claim 15, wherein in scan mode the component comprises a shift register embodied from the boundary scan cells and the scan-enable cells.

17. An electronic component in accordance with claim 14, wherein the scan-enable cells comprise a first control output to control an output buffer and a second control output to control at least one further output buffer.

18. An electronic component in accordance with claim 14, wherein each scan-enable cell is a boundary scan cell with two control outputs assigned to an output-enable flip-flop.

19. An electronic component in accordance with claim 14, wherein each output-enable flip-flop is connected via a control multiplexer to an output buffer to supply the control signal of the output-enable flip-flop to the output buffer in normal mode.

20. An electronic component in accordance with claim 14, wherein the scan mode is a boundary scan in accordance with the method standardized in IEEE 1149.

21. An electronic component in accordance with claim 15, wherein the scan-enable cells comprise a first control output to control an output buffer and a second control output to control at least one further output buffer.

22. An electronic component in accordance with claim 16, wherein the scan-enable cells comprise a first control output to control an output buffer and a second control output to control at least one further output buffer.

23. An electronic component in accordance with claim 15, wherein each scan-enable cell is a boundary scan cell with two control outputs assigned to an output-enable flip-flop.

24. An electronic component in accordance with claim 16, wherein each scan-enable cell is a boundary scan cell with two control outputs assigned to an output-enable flip-flop.

25. An electronic component in accordance with claim 19, wherein the control multiplexer is further connected to one of the scan-enable cells to supply the control signal of the scan-enable cell to the output buffer in scan mode.

26. An electronic component in accordance with claim 19, wherein the control multiplexer of the output-enable flip-flop, which is assigned to a scan-enable cell is the output multiplexer of the boundary scan cell.

27. An electronic component in accordance with claim 19, wherein the second control output of the scan-enable cell is connected via buffer control lines to at least one control multiplexer of a further output buffer.

28. An electronic component in accordance with claim 19, wherein the component comprises a central controller to supply mode control signals via mode control lines to the control multiplexers.

29. An electronic component in accordance with claim 28, wherein the central controller is further provided to supply mode control signals for switching all control multiplexers into the same state.

30. An electronic component in accordance with claim 28, wherein the central controller is further provided to also supply the mode control signals which control the control multiplexer to control multiplexers of the boundary scan cells which determine whether data is to be output from the output flip-flops or inserted data from the shift register via the output buffers.
